(19) United States
(12) Patent Application Publication
(10) Pub. No.: US 2025/0022871 A1
(43) Pub. Date: Jan. 16, 2025

(54) SEMICONDUCTOR DEVICE

(71) Applicant: Renesas Electronics Corporation, Tokyo (JP)

(72) Inventor: Yasuyuki MORISHITA, Tokyo (JP)

(73) Assignee: Renesas Electronics Corporation, Tokyo (JP)

(21) Appl. No.: 18/767,265

(22) Filed: Jul. 9, 2024

(30) Foreign Application Priority Data
Jul. 10, 2023 (JP) 2023-112739

(51) Int. Cl. H01L 27/02

(52) U.S. Cl. CPC H01L 27/0296; H01L 27/0255; H01L 27/0266

(57) ABSTRACT

A semiconductor device is provided. The semiconductor device includes an input/output cell, a core logic circuit, a first power supply cell, a second power supply cell, a third power supply cell and a fourth power supply cell. Each of the power supply cells includes a protection circuit and a bidirectional diode.

### CROSS-REFERENCE TO RELATED APPLICATIONS

The subject application claims priority under 35 U.S.C. § 119 to Japanese Patent Application No. 2023-112739 filed on Jul. 10, 2023. The entire disclosure of Japanese Patent Application No. 2023-112739 is incorporated herein by reference.

### BACKGROUND

The present disclosure relates to a semiconductor device, and is an effective technique applied to a semiconductor device having an electrostatic protection circuit.

There is a semiconductor device in which a signal inputted to an input/output pad electrode from the outside of a semiconductor device is sequentially transferred to an input/output cell including a ESD protective device (ESD: Electro-Static-Discharge) protective circuit) and an input/output logic circuit, and an internal circuit (core logic circuit) through a level shift circuit. Further, there is a semiconductor device in which an input/output cell and a power supply cell are arranged in a IO area provided along an edge portion of an outer periphery of a semiconductor chip, and an inner circuit is provided in a central area surrounded by a IO area of the semiconductor chip.

As a ESD test of a device, there is a CDM test. CDM test is a target charge model (CDM method: Charged Device Model), and is a test simulating a case where the semiconductor device itself to be tested is charged and static electricity is discharged from the semiconductor device to be tested. There are disclosed techniques listed below.
[Patent Document 1] Japanese Unexamined Patent Application Publication No. 2020-161721
[Patent Document 2] International Publication No. 2016/203648

### SUMMARY

In a CDM test for a semiconductor-device, an input-logic circuit or an internal-circuit may be more easily destroyed by a potential difference before a ESD protecting circuit.

It is an object of the present disclosure to provide a technique capable of securing high-resistance ESD and protecting a semiconductor device by a small-area ESD protector.

Other objects and novel features will become apparent from the description of this specification and the accompanying drawings.

An outline of representative ones of the present disclosure will be briefly described below.

According to an embodiment, the semiconductor device includes an input/output cell connected between the first power supply wiring and the first ground wiring, a core logic circuit connected between the second power supply wiring and the second ground wiring, a first power supply cell and a second power supply cell connected between the first power supply wiring and the first ground wiring, and a third power supply cell and a fourth power supply cell connected between the second power supply wiring and the second ground wiring. Each of the first claim supply cell, the second power supply cell, the third power supply cell, and the fourth power supply cell includes a protection circuit connected between a corresponding power supply line and a corresponding ground line, and a bidirectional diode connected between the first ground line and the second ground line.

According to the semiconductor device of the above embodiment, the semiconductor device can be protected by a ESD protector having a small area while ensuring a high-level ESD resistance.

### BRIEF DESCRIPTION OF THE DRAWINGS

FIG. 1 is an overall layout arrangement diagram of a semiconductor device according to a first embodiment.

FIG. 2 is a schematic block diagram of a semiconductor device according to the first embodiment.

FIG. 3 is a schematic layout arrangement diagram of the semiconductor device of FIG. 2.

FIG. 4 is a diagram for explaining effects of the semiconductor device according to the first embodiment.

FIG. 5 is a schematic block diagram of a semiconductor device according to a second embodiment.

FIG. 6 is a schematic layout arrangement diagram of the semiconductor device of FIG. 5.

FIG. 7 is a schematic block diagram of a semiconductor device according to a comparative example 1.

FIG. 8 is a schematic layout arrangement diagram of a semiconductor device according to the comparative example 1.

FIG. 9 is a schematic block diagram of a semiconductor device according to a comparative example 2.

FIG. 10 is a schematic layout arrangement diagram of a semiconductor device according to the comparative example 2.

FIG. 11 is a diagram for explaining a problem of the semiconductor device according to the comparative example 1.

FIG. 12 is a diagram for explaining another problem of the semiconductor device according to the comparative example 1.

FIG. 13 is a diagram for explaining a problem of the semiconductor device according to the comparative example 2.

FIG. 14 is a diagram for explaining another problem of the semiconductor device according to the comparative example 2.

### DETAILED DESCRIPTION

Hereinafter, Embodiment will be described with reference to the drawings. However, in the following description, the same components are denoted by the same reference numerals, and a repetitive description thereof may be omitted. It should be noted that the drawings may be represented schematically in comparison with actual embodiments for the sake of clarity of explanation, but are merely an example and do not limit the interpretation of the present invention.

### First Embodiment

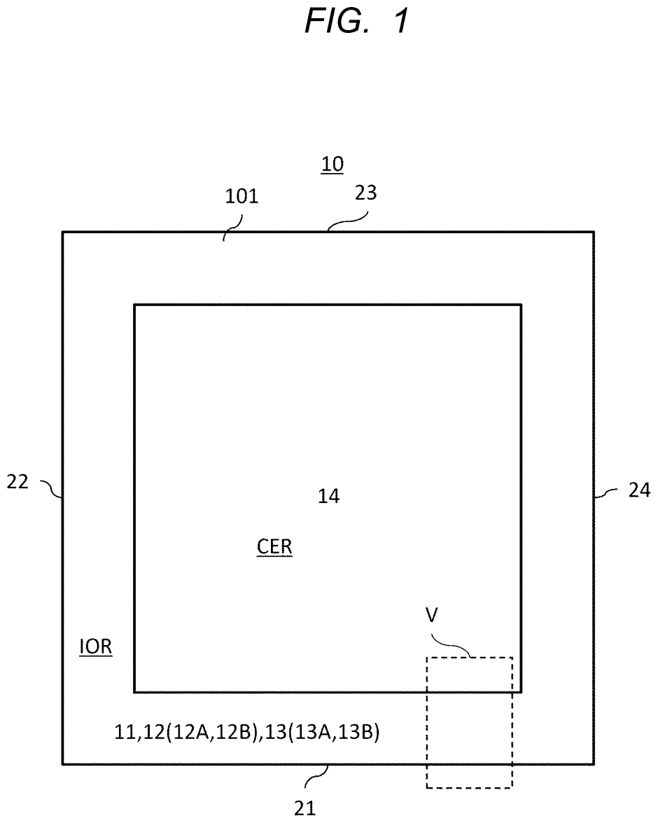

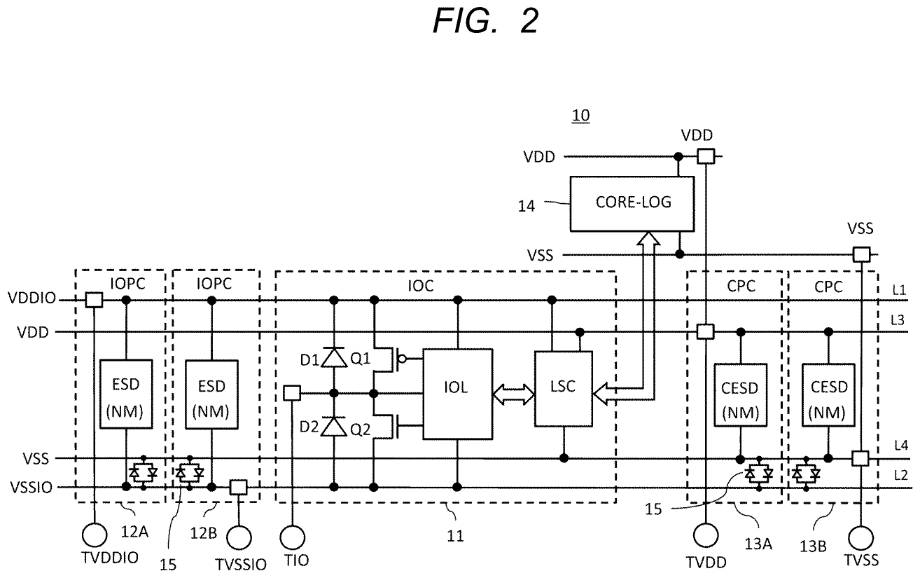

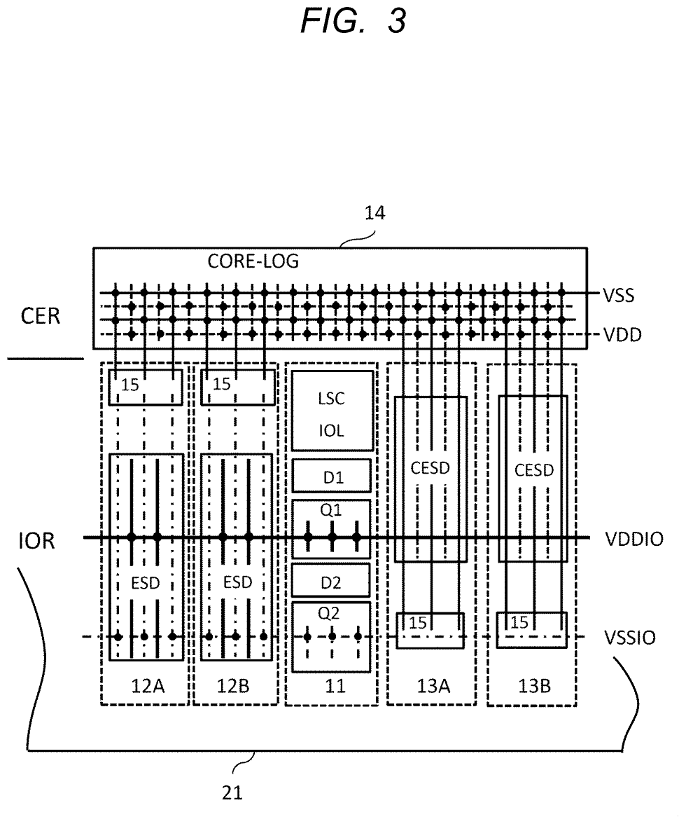

The semiconductor device 10 according to the first embodiment will be described with reference to FIG. 1 to FIG. 3. FIG. 1 is an overall layout arrangement diagram of a semiconductor device according to a first embodiment. FIG. 2 is a schematic block diagram of a semiconductor device according to t first embodiment. FIG. 3 is a schematic layout arrangement diagram of the semiconductor device of FIG. 2. In FIG. 1, the layout arrangement of the region indicated by the dotted line Vis shown in FIG. 3.

As illustrated in FIG. 1, the semiconductor device 10 includes an input/output cell (IOC) 11, a first power cell (IO power cell IOPC) 12 (IO power cell 12A, IO power cell 12B), and a second power cell (a core power cell CPC) 13 (a core power cell 13A, a core power cell 13B) at an outer peripheral portion of a rectangular semiconductor chip 101 such as single-crystal silicon. IO power cell 12A may be referred to as a first power cell, IO power cell 12B may be referred to as a second power cell, the core power cell 13A may be referred to as a third power cell, and the core power cell 13B may be referred to as a fourth power cell.

An area in which the input/output cell 11, the first power supply cell 12, and the second power supply cell 13 are disposed is referred to as a IO area IOR. IO region IOR is provided along the four sides 21, 22, 23, and 24 of the chip end portion (edge) of the semiconductor chip 101 in a plan view. The four sides 21, 22, 23, and 24 include a first side 21, a third side 23 provided opposite to the first side 21, a second side 22 provided between the first side 21 and the third side 23, and a fourth side 24 provided opposite to the second side 22.

The device 10 also includes an inner circuit 14 as a core logic circuit (CORE-LOG). A core logic region (also referred to as a central region and a second region) CER in which the inner circuit 14 is disposed is provided in a central portion of the semiconductor chip 101 and is a region surrounded by IO region.

The input/output cell 11 is a formation region of an input/output circuit connected to one input/output pad. The power supply cells 12 and 13 are ESD protective circuits (CESD, ESD) for protecting the device 10 from ESD (ESD: Electro-Static-Discharge and noises, and wires for supplying a power supply potential (VDDIO, VDD) or a grounding potential (VSSIO, VSS) to the inside of the chip.

Since it is necessary to reduce the power supply impedance uniformly, the power supply cells 12 and 13 are arranged in a distributed manner for each input/output cell 11, and are arranged adjacent to each other between the input/output cell 11 and the input/output cell 11.

The power supply potential (VDDIO, VDD) includes a first power supply potential VDDIO of the input/output cell 11 and a second power supply potential VDD of the inner circuit 14. Similarly, the ground potential (VSSIO, VSS) includes a first ground potential VSSIO of the input/output cell 11 and a second ground potential VSS of the inner circuit 14. The first power supply potential VDDIO may be a potential (VDDIO>VDD) greater than the second power supply potential VDD. The first power supply potential VDDIO, the first ground potential VSSIO, the second power supply potential VDD, and the second ground potential VSS are supplied to the input/output cell 11 via a power supply line. The second power supply potential VDD and the second grounding potential VSS are supplied to the inner circuit 14 via a power supply line.

IO power supply cell 12A includes a ESD protecting circuit (ESD) and a bridging circuit 15, and supplies the first power supply potential VDDIO to the power supply wiring (first power supply wiring L1). IO power supply cell 12B includes a ESD protecting circuit (ESD) and a bridging circuit 15, and supplies a first ground potential VSSIO to a power supply wiring (L2: also referred to as a first ground wiring). ESD protector (ESD) may comprise an N-channel MOS transistor NM.

The core-power supply cell 13A includes a ESD protecting circuit (CESD) and a bridging circuit 15, and supplies the second power supply potential VDD to the power supply wiring (second power supply wiring L3). The core-power supply cell 13B includes a ESD protecting circuit (CESD) and a bridging circuit 15, and supplies a second ground potential VSS to a power supply wiring (L4: also referred to as a second ground wiring). ESD protector (CESD) may comprise an N-channel MOS transistor NM.

ESD protective circuit (ESD) (i.e., the source-drain path of the N-channel MOS transistor NM constituting ESD protective circuit (ESD)) is connected between the power supply line to which the first power supply potential VDDIO is supplied and the power supply line to which the first grounding potential VSSIO is supplied. ESD protecting circuit (CESD) (that is, the source-drain path of the N-channel MOS transistor NM constituting ESD protecting circuit (CESD)) is connected between the power supply wiring to which the second power supply potential VDD is supplied and the power supply wiring to which the second grounding potential VSS is supplied.

The bridging circuit 15 includes a pair of bi-directional diodes connected between the power supply wiring to which the first ground potential VSSIO is supplied and the power supply wiring to which the second ground potential VSS is supplied, and connecting the power supply wiring to which the first ground potential VSSIO is supplied and the power supply wiring to which the second ground potential VSS is supplied. The anode of one of the diodes is connected to a power supply line to which the first ground potential VSSIO is supplied, and the cathode is connected to a power supply line to which the second ground potential VSS is supplied. The anode of the other diode is connected to the power supply wiring to which the second ground potential VSS is supplied, and the cathode is connected to the power supply wiring to which the first ground potential VSSIO is supplied. The bridge circuit 15 can also be referred to as a bi-directional diode 15.

The input/output cell 11 includes an input/output circuit connected to an input/output terminal (TIO). The input/output terminal TIO, the power supply terminal TVDD, TVDDIO, and the grounding terminal TVSS, TVSSIO are disposed on the input/output cell 11, IO power supply cell 12, and the core power supply cell 13, respectively, but may be disposed apart from the input/output cell 11, IO power supply cell 12, and the core power supply cell 13, respectively. The input/output terminal TIO, the power supply terminal TVDD, TVDDIO, and the ground terminal TVSS, TVSSIO are connected to a bonding wire or the like, and are also referred to as an input/output pad, a power supply pad, and a ground pad, respectively.

The input/output circuit constituting the input/output cell 11 includes a diode D1, D2 constituting a ESD protecting circuit, and an output circuit including a P-channel transistor Q1 and an N-channel transistor Q2 as output transistors for transmitting an output signal to a signal line connected to the input/output terminal TIO. An input/output logic circuit IOL including a CMOS inverter that receives an input signal input from the input/output terminal TIO via a signal line, and a level shifter circuit LSC are provided. The input/output circuit further receives an input signal input from the input/output terminal TIO via a signal line, and is input to the level shifter circuit LSC via the input/output logic circuit IOL, is level-converted by the level shifter circuit LSC, and is supplied to the inner circuit 14. On the other hand, the signal output from the internal circuit 14 is input to the level shifter circuit LSC, is level-converted, is supplied to the input/output logic circuit IOL, and is output as an output signal from the output circuit including the P-channel transistor Q1 and the N-channel transistor Q2 to the input/output terminal TIO. The P-channel transistor Q1 and the N-channel transistor Q2 may be formed of MOS transistors.

The source-drain path of the P-channel transistor Q1 is connected between the power supply line of the first power supply potential VDDIO and the signal line from the input/output terminal TIO, and the source-drain path of the N-channel transistor Q2 is connected between the signal line and the ground line of the first ground potential VSSIO. The anode of the diode D1 is connected to the signal wiring from the input/output terminal TIO, and the cathode thereof is connected to the power supply wiring of the first power supply potential VDDIO. The anode of the diode D2 is connected to the ground wiring of the first ground potential VSSIO, and the cathode thereof is connected to the signal wiring from the input/output terminal TIO. The diode D1 supplies a surge current from the input/output terminal TIO to the power supply terminal VDDIO via the signal wiring and the power supply wiring of the first power supply potential VDDIO, and the diode D2 supplies a surge current from the ground terminal TVDDIO to the input/output terminal TIO via the ground wiring and the signal wiring of the first ground potential VSSIO. The output-circuit may be a so-called open-drain type that does not have a P-channel transistor Q1. In addition, the input/output circuit may not include any one of the output circuit and the input circuit.

The input/output logic IOL is connected between a power supply line of the first power supply potential VDDIO and a ground line of the first ground potential VSSIO. The level shifter LSC is connected between a circuit supply line of the first power supply potential VDDIO, a power supply line to which the second power supply potential VDD is supplied, and a power supply line to which the second grounding potential VSS is supplied.

The power cell 12A,13A comprises a ESD protection circuit (CESD, ESD) corresponding to a power terminal (TVDDIO, TVDD), and the power cell 12B, 13B comprises a ESD protection circuit (CESD, ESD) corresponding to a grounding terminal (TVSSIO,TVSS).

The first power supply potential VDDIO is, for example, 1.8V (or 3.3V), and the second power supply potential VDD is, for example, 0.8V. The grounding terminal (TVSSIO,TVSS) is, for example, a 0.0V.

For example, when the first power supply potential VDDIO is 1.8V and the second power supply potential VDD is 0.8V, 1) the transistor Q1, Q2 of the output circuit and the input/output logic circuit IOL are configured only by a MOSFET (1.8V-MOS having a 1.8V breakdown voltage. 2) The inner circuit 14 is composed of only a MOSFET (also referred to as a core MOS) having a 0.8V withstand voltage. 3) The level shifter LSC includes a 1.8V-MOS and a core MOS. 4) The core power supply cell 13A, 13B protects the core MOS of the inner circuit 14 and the core MOS of the level shifter circuit LSC. 5) IO power supply cell 12A, 12B protects the transistor Q1, Q2 of the output circuit and 1.8V-MOS of the input/output logic circuit IOL.

FIG. 3 shows the arrangement of IO power supply cell 12A, 12B arranged in IO region IOR, one input/output cell 11 and the core power supply cell 13A, 13B, and the inner circuitry 14 arranged in the core logic area. As shown in FIG. 3, in IO region IOR, IO power supply cell 12A, 12B, one input/output cell 11, and the core power supply cell 13A, 13B are arranged in this order, and the inner circuitry 14 is arranged adjacently to IO area IOR in the core logic area CER above IO area.

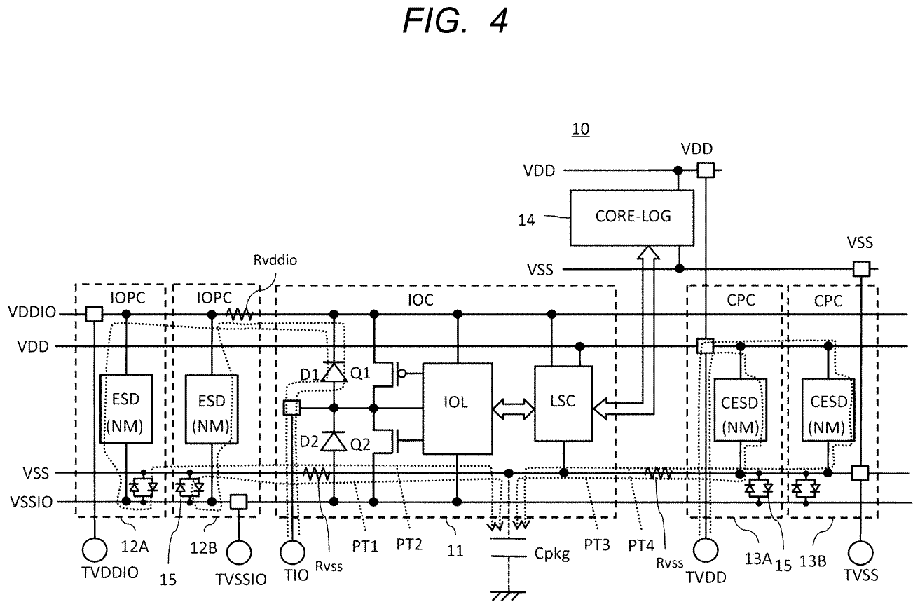

FIG. 4 is a diagram for explaining effects of the semiconductor device according to the first embodiment. Here, in CDM test, which is one of the electrostatic tests, a case where a current flows into the capacitive components Cpkg parasitic to the power supply wire to which the second grounding potential VSS is supplied is examined. In FIG. 4, a first CDM test on the input/output terminal TIO and a second CDM test on the power supply terminal TVDD are assumed.

1) In the first CDM test, as described below, there are a first charging path PT1 and a second charging path PT2. First charging path PT1: TIO->D1->power supply wiring of the first power supply potential VDDIO->ESD of 12B->power supply wiring to which the first ground potential VSSIO is supplied->15 of 12B->power supply wiring to which the second ground potential VSS is supplied->Cpkg. Second charging path PT2: TIO->D1->power supply wiring of the first power supply potential VDDIO->ESD of 12A->power supply wiring to which the first ground potential VSSIO is supplied->15 of 12A->power supply wiring to which the second ground potential VSS is supplied->Cpkg.

2) In the second CDM test, as described below, there are a third charging path PT3 and a fourth charging path PT4. The third charge path PT3: TVDD->the power supply wiring to which the second power supply potential VDD is supplied->CESD of 13A->the power supply wiring to which the second ground potential VSS is supplied->Cpkg. The fourth charge path PT4: TVDD->the power supply wiring to which the second power supply potential VDD is supplied->CESD of 13B->the power supply wiring to which the second grounding potential VSS is supplied->Cpkg.

That is, the semiconductor device 10 of the first embodiment has the following features.

1) The bidirectional diode 15 between the power supply line to which the first ground potential VSSIO is supplied and the power supply line to which the second ground potential VSS is supplied is disposed in each of IO power supply cell 12A, 12B and the core power supply cell 13A, 13B.

2) In the first TIO test for the input/output terminals, in the first CDM test, without depending on the layout arrangement of the input/output cells 11 and the core power supply cells 13B, it is possible to easily form a discharging path (PT1, 2) from the input/output terminals TIO to the power supply line to which the second grounding potential VSS parasitic on the capacitance components Cpkg is supplied.

3) According to the above 2, TIO of the input/output terminal makes it difficult for the input/output terminal to be affected by the parasitic resistance VSS of the power supply wiring to which the first power supply potential VDDIO is supplied and the parasitic resistance Rvss of the power supply wiring to which the second ground potential VSS is supplied, even with respect to CDM current flowing through the power supply wiring to which the second ground potential VSS is supplied, and thus it is possible to avoid breakdown due to the potential difference of the input/output logic circuit IOL.

4) A ESD protecting circuit (CESD) is disposed in each of the core-power supply cells 13A,13B, and in the second CDM test for the power supply terminal TVDD, it is possible to secure a satisfactory discharge path discharge path (PATH3, 4) to the power supply line to which the second grounding potential VSS in which the capacitance components Cpkg are parasitic from the power supply terminal TVDD is supplied.

5) With the above 4, breakdown due to the potential difference of the internal circuit 14 can also be avoided.

6) The bidirectional diode 15 of IO power supply cell 12A,12B shown in FIG. 3 is disposed on 12A, 12B of IO power supply cell (in FIG. 3, the upper end) facing the inner circuit 14. On the other hand, the bidirectional diode 15 of the core power supply cell 13A, 13B is not disposed on the side of the core power supply cell 13A, 13B facing the internal circuit 14, but is disposed on the side facing the chip edge side (the side of the four sides 21, 22, 23, 24 of the chip end portion in FIG. 1) of the semiconductor chip 101 of the core power supply cell 13A,13B (in FIG. 3, the lower end portion). These bi-directional diode 15 arrangement positions have the smallest effect of parasitic resistivity in forming a discharging path between the power supply wiring to which the first ground potential VSSIO is supplied and the power supply wiring to which the second ground potential VSS is supplied.

### Second Embodiment

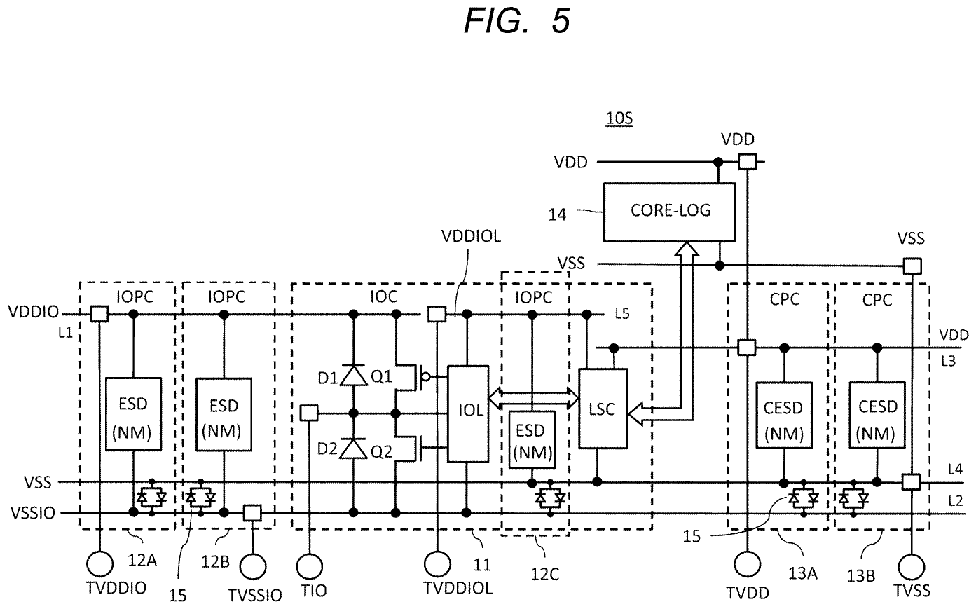

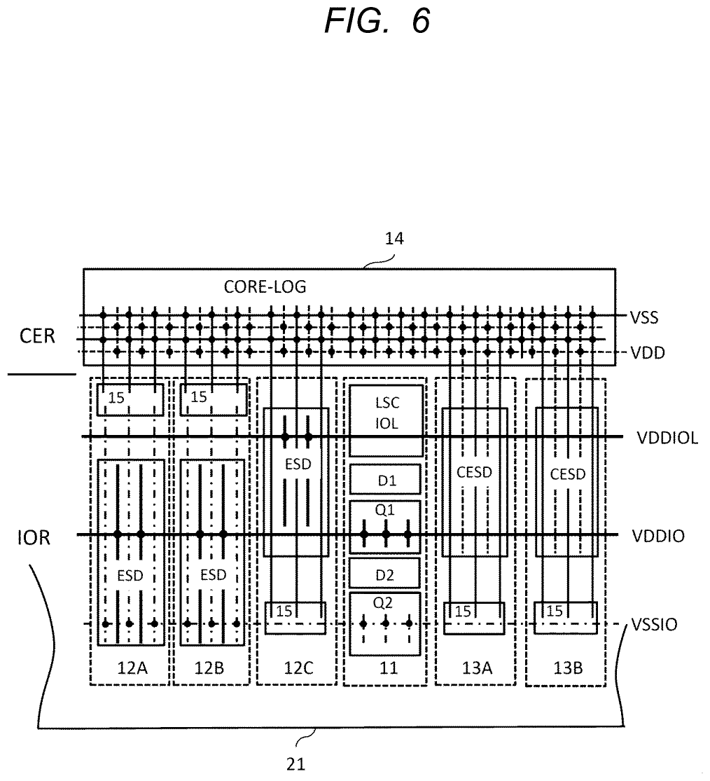

Next, 10S according to the second embodiment will be described with reference to FIG. 5 and FIG. 6. FIG. 5 is a schematic block diagram of a semiconductor device according to a second embodiment. FIG. 6 is a schematic layout arrangement diagram of the semiconductor device of FIG. 5.

The semiconductor device 10S according to the second embodiment shown in FIG. 5 differs from the semiconductor device 10 according to the first embodiment shown in FIG. 2 in that (1) the power supply wiring (L1) of the first power supply potential VDDIO is separated and the power supply potential VDDIOL for the input/output logic circuit IOL is supplied (also referred to as the fourth power supply wiring (L5)). The power supply line of the first power supply potential VDDIO may be referred to as a third power supply line (L1). The power supply potential VDDIOL is connected to the power supply terminal TVDDIOL, and the power supply potential 3) IO as the power supply cell IOPC for IO (fifth power supply cell) 12C is connected between the power supply potential VDDIOL and the power supply line to which the second grounding potential VSS is supplied.

Here, the basic configuration of IO power supply cell 12C is the same as that of IO power supply cell 12A,12B.

Further, as illustrated in FIG. 6, in IO region 12C, the power supply cell for IOR is disposed in an area between IO power supply cell 12B and the input/output cell 11. The bi-directional diode 15 is also disposed in the added IO power supply cell 12C, and contributes to forming a discharging path to escape from the power supply line to which the second grounding potential VSS is supplied.

In the input/output cell 11, power supply lines to which the power supply potential VDDIOL is supplied are laid out in the upper half of the input/output cell 11 in accordance with the input/output logic IOL.

In IO power supply cell 12C, a power supply line to which the power supply potential VDDIOL is supplied and a power supply line to which the second grounding potential VSS is supplied are vertically laid out.

Therefore, the bidirectional diode 15 in IO power supply cell 12C is disposed on the side (the lower end part in FIG. 3) facing the chip edge side (the side of the four sides 21, 22, 23, and 24 of the chip end part in FIG. 1) of the semiconductor chip 101. Therefore, the arrangement of the bidirectional diodes 15 in IO power supply cell 12C is the most efficient layout arrangement in forming the discharging path between the power supply line to which the first ground potential VSSIO is supplied and the power supply line to which the second ground potential VSS is supplied, as is the arrangement of the bidirectional diodes 15 in the core power supply cell 13A, 13B.

With this configuration, the same effects as those of the first embodiment can be obtained. Further, since the noise of the power supply line of the first power supply potential VDDIO can be reduced from propagating to the input/output logic circuit IOL, the performance of the input/output logic circuit IOL can be improved (increased speed).

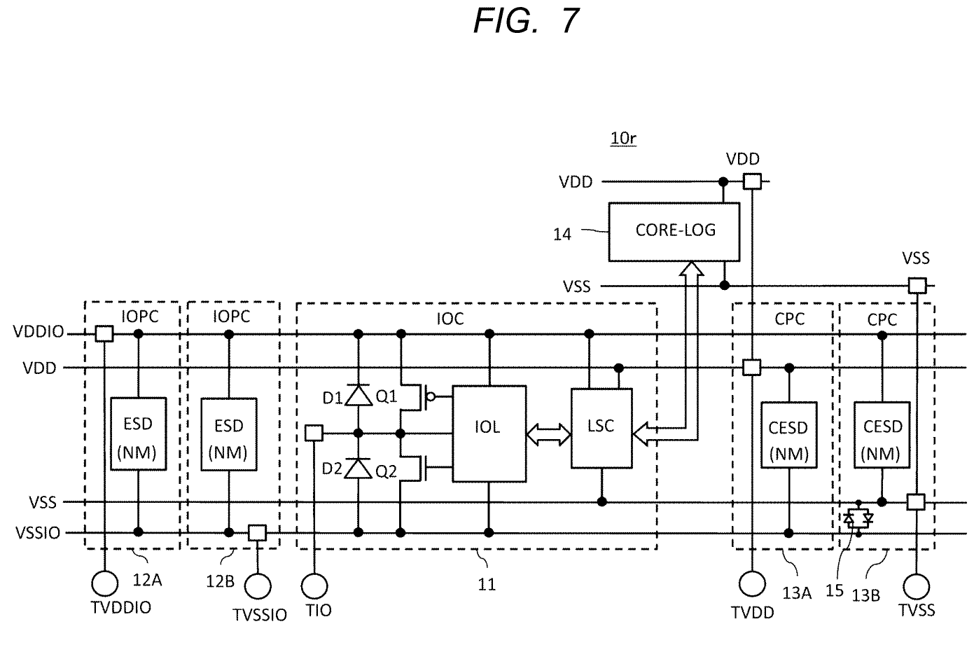

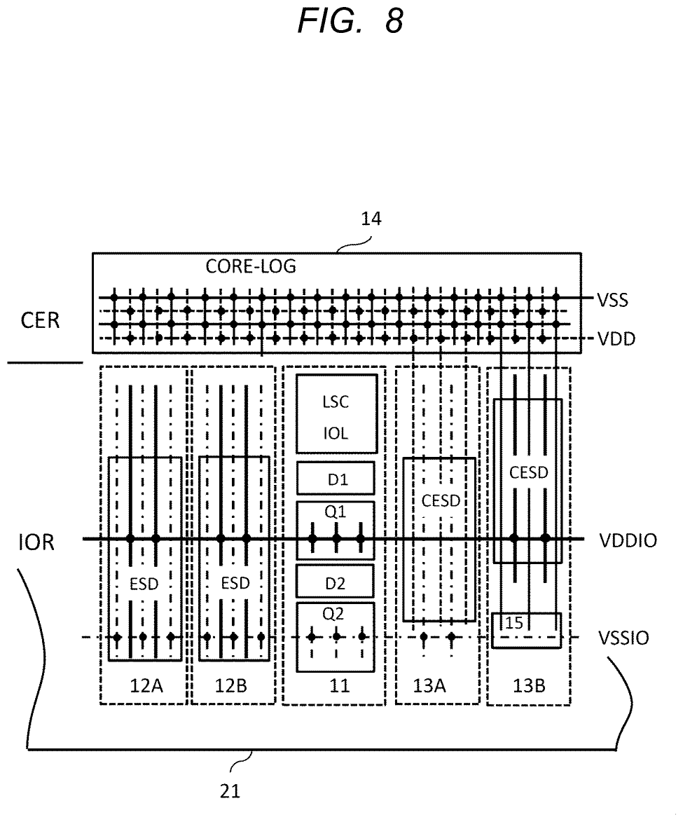

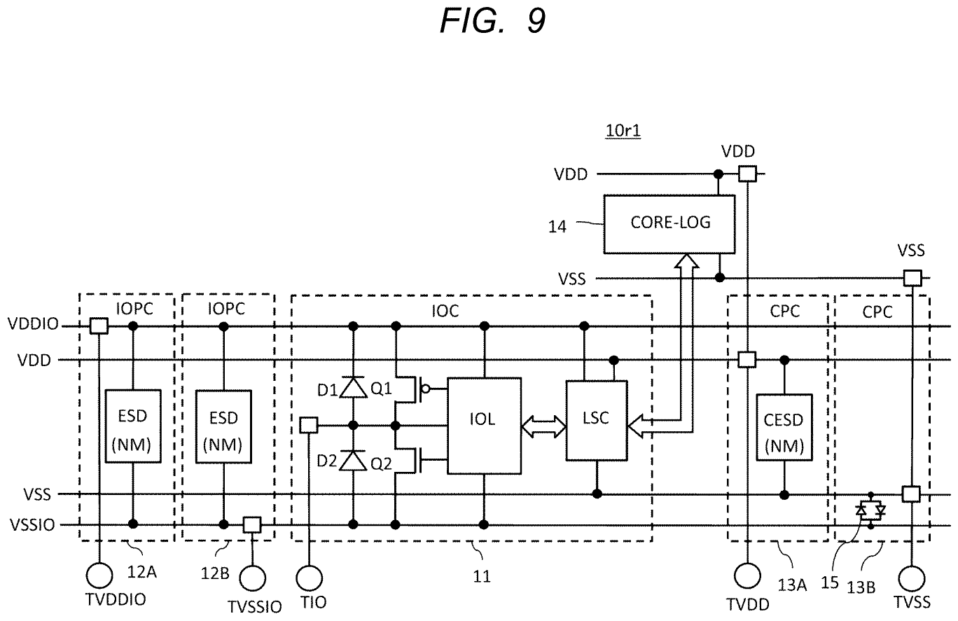

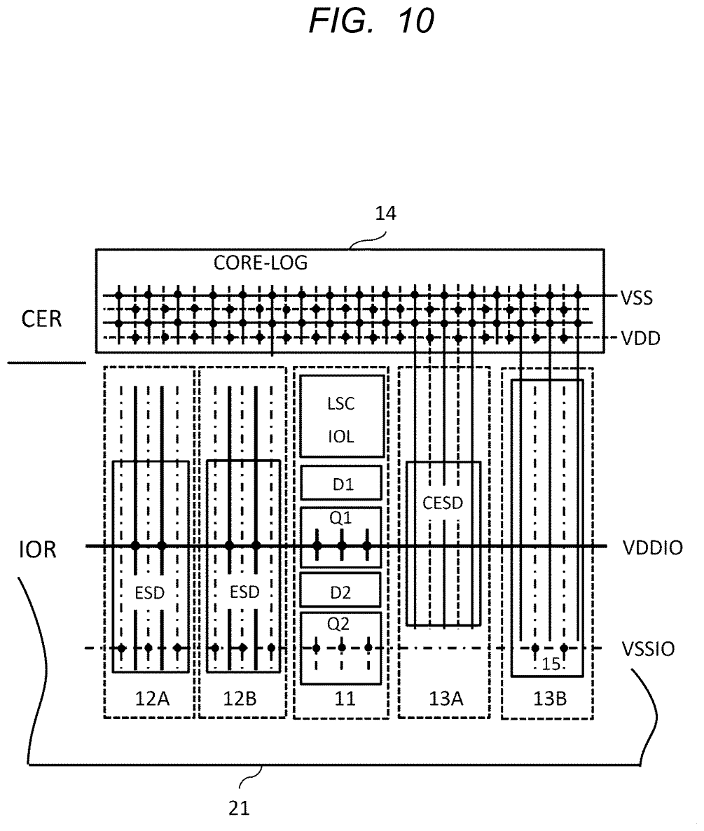

FIG. 7 is a schematic block diagram of the semiconductor device according to Comparative Example 1. FIG. 8 is a schematic layout arrangement diagram of a semiconductor device according to Comparative Example 1. FIG. 9 is a schematic block diagram of a semiconductor device according to Comparative Example 2. FIG. 10 is a schematic layout arrangement diagram of a semiconductor device according to Comparative Example 2.

As shown in FIGS. 7 and 8, in the semiconductor device 10r of Comparative Example 1, the bidirectional diode 15 is not provided in IO power supply cell 12A, 12B and the core power supply cell 13A with respect to the semiconductor device 10 of FIG. 2. Further, in the core power supply cell 13A of the semiconductor device 10r, ESD protector (CESD) is connected between the power supply line to which the second power supply potential VDD is supplied and the power supply line to which the first grounding potential VSSIO is supplied. In the core power supply cell 13B of the semiconductor device 10r, ESD protector (CESD) is connected between the power supply line to which the first power supply potential VDDIO is supplied and the power supply line to which the second grounding potential VSS is supplied.

As shown in FIGS. 9 and 10, in the semiconductor device 10r1 of Comparative Example 2, ESD protective circuit (CESD) of the core power supply cell 13A is connected between the power supply wiring to which the second power supply potential VDD is supplied and the power supply wiring to which the second grounding potential VSS is supplied, with respect to the semiconductor device 10r of Comparative Example 1. The core-power supply cell 13B of the semiconductor device 10r1 is not provided with a ESD protector (CESD).

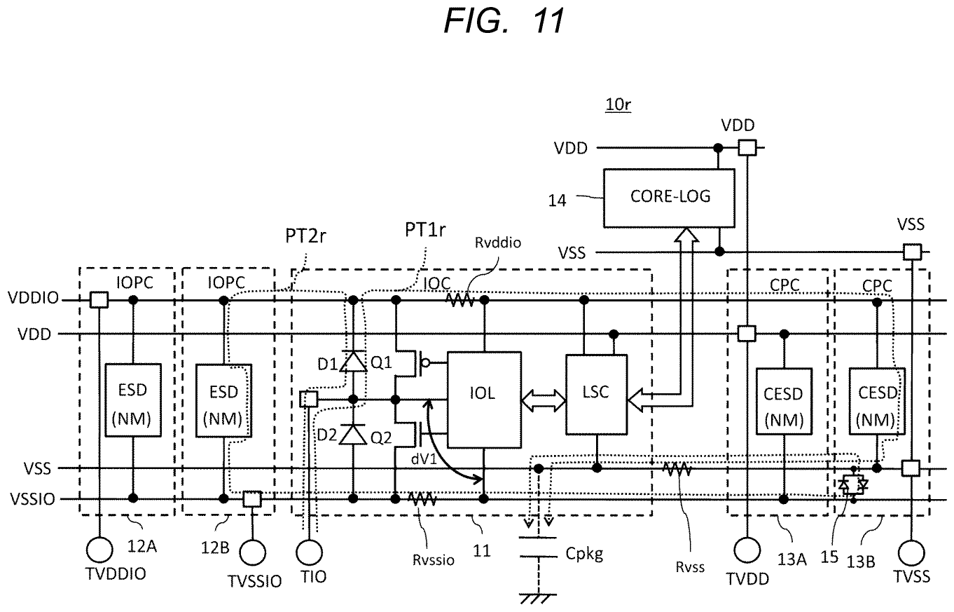

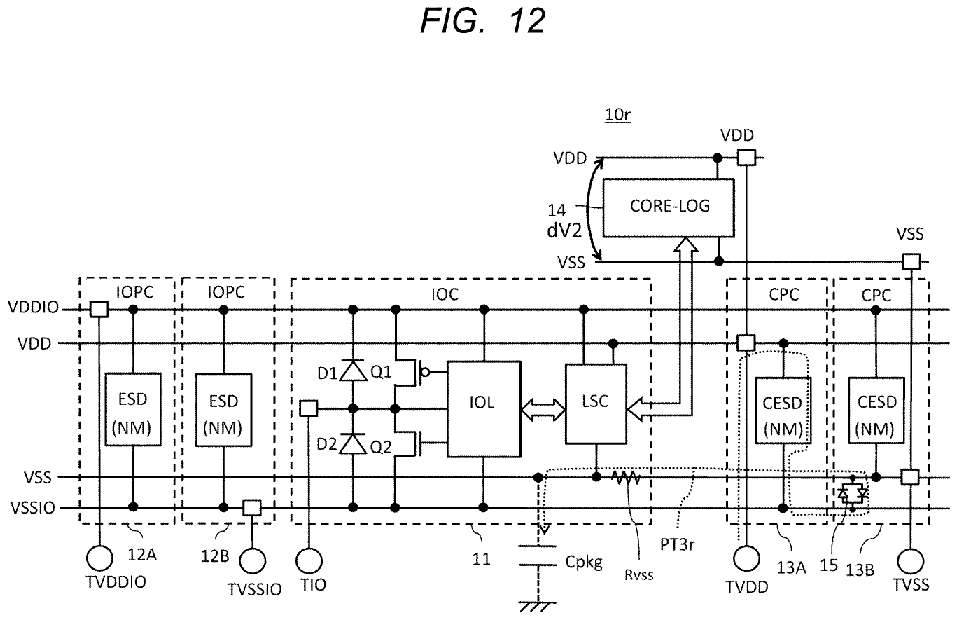

FIG. 11 is a diagram for explaining a problem of the semiconductor device according to a comparative example 1. FIG. 12 is a diagram for explaining another problem of the semiconductor device according to the comparative example 1.

As shown in FIG. 11, in CDM test, which is one of the electrostatic tests, a current flows into a discharging path (PT1r, PT2r) to the power supply line to which the second grounding potential VSS parasitic on the capacitance components Cpkg is supplied from the input/output terminal TIO. When the protected circuit becomes fragile due to the miniaturization of the semiconductor device structure, the parasitic resistance Rvddio of the power supply wiring to which the first ground potential VSSIO is supplied, the parasitic resistance Rvssio of the power supply wiring to which the first ground potential VSSIO is supplied, and the parasitic resistance Rvss of the power supply wiring to which the second ground potential VSS is supplied have been influenced, and a problem has been found that the input/output logic circuit IOL is destroyed by the potential difference dV1 in CDM test. In order to overcome this problem in Comparative Example 1, there is a need to reduce the parasitic resistance 13B of the power supply line to which the second ground potential VSS is supplied by increasing the cell width of the power supply cell Rvss for the core, and also to reduce the parasitic resistance Rvssio of the power supply line to which the first ground potential VSSIO is supplied by providing a strict arrangement constraint between the cells of the input/output cell 11 and the power supply cell for the core. It has been found that the chip-size of the semiconductor-device 10r increases and the degree of freedom in designing is hindered.

As shown in FIG. 12, ESD protecting circuit (CESD) in the core-use power supply cell 13A is connected between the power supply wiring to which the second power supply potential VDD is supplied and the power supply wiring to which the first grounding potential VSSIO is supplied. Therefore, in CDM test to the power supply terminal TVDD, a current flows from the power supply terminal TVDD through the bidirectional diode 15 to the capacitance components Cpkg parasitic to the power supply line to which the second grounding potential VSS is supplied, as indicated by the discharging path PT3r. In addition, the potential difference dV2 generated by the bidirectional diode 15 also stresses the internal circuit 14, and the internal circuit 14 is easily destroyed by the potential difference dV2. In particular, since a plurality of thin-film MOS transistors having relatively thin gate-oxide films are used in the inner-circuit 14, they are susceptible to potential difference stress.

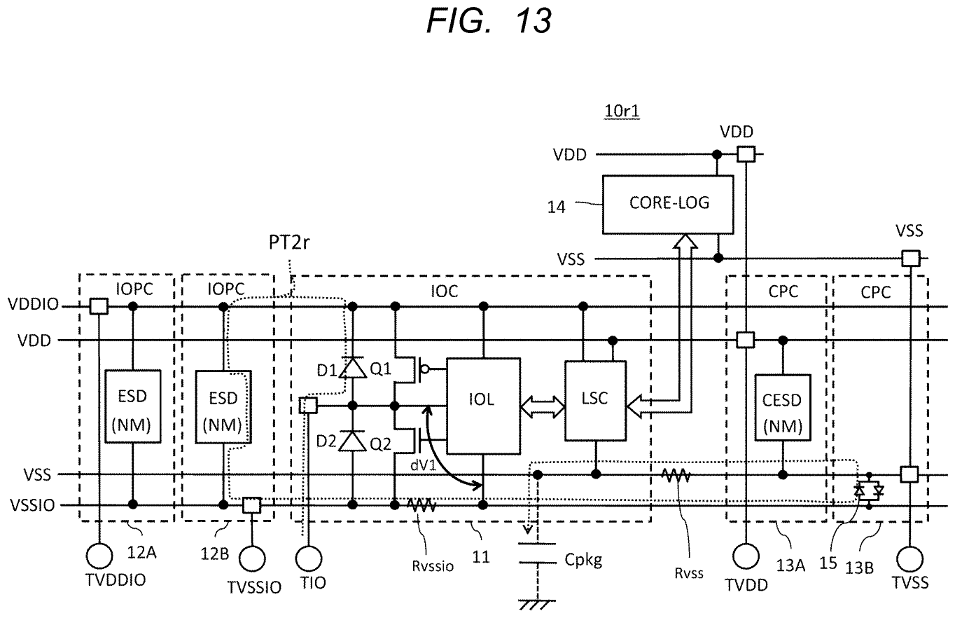

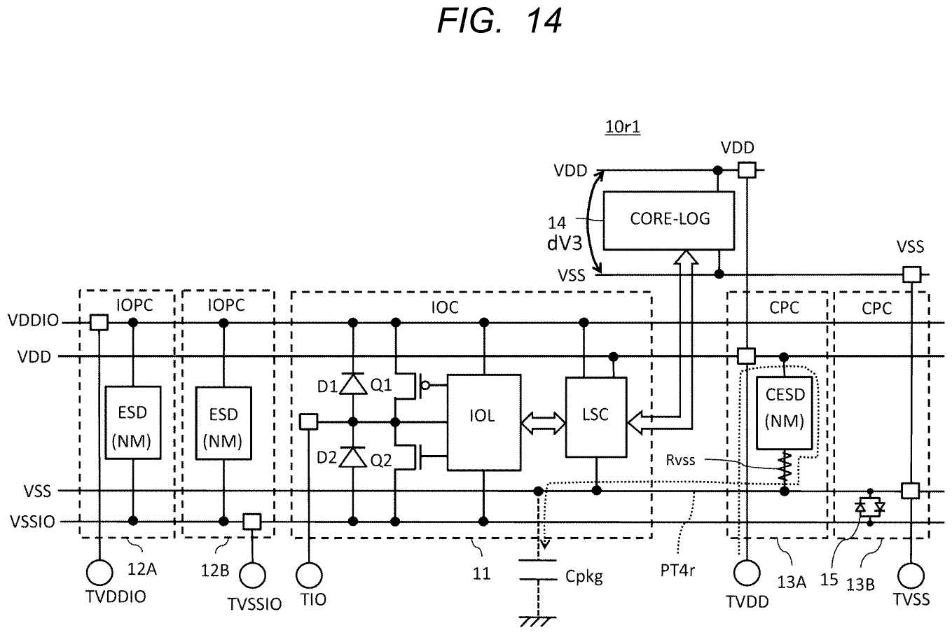

FIG. 13 is a diagram for explaining a problem of the semiconductor device according to a comparative example 2. FIG. 14 is a diagram for explaining another problem of the semiconductor device according to the comparative example 2.

As shown in FIG. 13, in the comparative example 2, since the discharge path PT2r is formed in the same manner as in the comparative example 1 of FIG. 11, there is a problem that the input/output logic IOL is destroyed by the potential difference dV1 in CDM test in the same manner as in the comparative example 1. As shown in FIG. 14, also in the comparative example 2, in CDM test to the power supply terminal TVDD, the discharging path PT4r from the power supply terminal TVDD to the capacitive components Cpkg is formed. In the semiconductor device 10r1 of the comparative example 2, only the core power supply cell 13A is provided with ESD protection circuit (CESD), and there is no ESD protection circuit (CESD) in the core power supply cell 13B. Therefore, as shown in FIG. 13, in CDM test to the power supply terminal TVDD, the discharging performance of ESD protecting circuit (CESD) becomes insufficient, and when the protected circuit becomes fragile with the miniaturization of the semiconductor device structure, the inner circuit 14 is easily destroyed by the potential difference dV3. When the number of ESD protective circuits (CESD) in the core-power supply cell 13A is small, the parasitic resistivity Rvss of the vertical wiring provided in the vertical direction between ESD protective circuit (CESD) and the power supply wiring to which the second grounding potential VSS is supplied is also easily affected.

According to the first and second embodiments, the problems and problems described in the comparative example 1 and the comparative example 2 can be avoided, so that it is possible to secure a high-level ESD resistance and to protect the device by a small-area ESD protector.

Although the present disclosure has been described in detail based on the embodiments, it is needless to say that the present disclosure is not limited to the above-described embodiments and can be variously modified.

What is claimed is:

1. A semiconductor device comprising:
a first power supply wiring configured to supply a first power supply voltage;
a second power supply wiring configured to supply a second power supply voltage;
a first ground wiring configured to supply a first ground voltage;
a second ground wiring configured to supply a second ground voltage;
an I/O cell connected between the first power supply wiring and the first ground wiring;
a core logic circuit connected between the second power supply wiring and the second ground wiring;
a first power supply cell and a second power supply cell connected between the first power supply wiring and the first ground wiring; and
a third power supply cell and the fourth power supply cell connected between the second power supply wiring and the second ground wiring,
wherein each of the first, second, third and fourth power supply cell includes:
a protection circuit connected between the corresponding power supply wiring and the corresponding ground wiring; and
a bi-directional diode connected between the first ground wiring and the second ground wiring.

2. The semiconductor device according to claim 1,
wherein each bi-directional diode of the first and second power supply cell is disposed between the core logic circuit and the protection circuit therein in a plan view, and
wherein each bi-directional diode of the third and fourth power supply cell is disposed at a chip side so that the protection circuit is disposed between the core logic circuit and the bi-directional diode in the plan view.

3. The semiconductor device according to claim 2,
wherein the IO cell includes an output transistor and an IO logic circuit,
wherein the first power supply wiring includes:
a third power supply wiring connected to the output transistor; and
a fourth power supply wiring connected to the IO logic circuit and separated from the third power supply wiring,
wherein the IO logic circuit connected between the fourth power supply wiring and the first ground wiring,
wherein the semiconductor device further comprises a fifth power supply cell connected between the fourth power supply wiring and the first ground wiring,
wherein the fifth power supply cell includes:
a protection circuit connected between the fourth power supply wiring and the first ground wiring; and
a bi-directional diode connected between the first ground wiring and the second ground wiring.

4. The semiconductor device according to claim 3,
wherein the bi-directional diode of the fifth power supply cell is disposed at a chip side so that the protection circuit of the fifth power supply cell is disposed between the core logic circuit and the bi-directional diode in the plan view.

5. The semiconductor device according to claim 3,
wherein, between the core logic circuit and the chip side, the circuits are arranged in the order of the first power supply cell, the second power supply cell, the IO cell, the third power supply cell and the fourth power supply cell.

6. The semiconductor device according to claim 4,
wherein, between the core logic circuit and the chip side, the circuits are arranged in the order of the first power supply cell, the second power supply cell, the fifth power supply cell, the IO cell, the third power supply cell and the fourth power supply cell.
